(19) United States
(12) Patent Application Publication
(10) Pub. No.: US 2008/0230929 A1
(43) Pub. Date: Sep. 25, 2008

(54) OVERLAY MARK OF SEMICONDUCTOR DEVICE AND SEMICONDUCTOR DEVICE INCLUDING THE OVERLAY MARK

(75) Inventors: Jang-ho Shin, Seoul (KR); Chan-hoon Park, Seoul (KR); Jung-Hyeon Lee, Gyeonggi-do (KR); Suk-joo Lee, Gyeonggi-do (KR); Hyun-tae Kang, Gyeonggi-do (KR); Jeong-hee Cho, Gyeonggi-do (KR); Young-hoon Song, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/042,377

(22) Filed: Mar. 5, 2008

(30) Foreign Application Priority Data
Mar. 20, 2007 (KR) 10-2007-0027224

(51) Int. Cl. H01L 23/544

(52) U.S. Cl. 257/797; 257/E23.179

(57) ABSTRACT

Provided are an overlay mark of a semiconductor device and a semiconductor device including the overlay mark. The overlay mark includes: reference marks formed in rectangular shapes comprising sides in which fine patterns are formed; and comparison marks formed as rectangular shapes which are smaller than the rectangular shapes of the reference marks and formed of fine patterns, wherein the number of comparison marks is equal to the number of reference marks, wherein the reference marks and the comparison marks are formed on different thin films formed on a semiconductor substrate to be used to inspect alignment states of the different thin films, and the overlay mark reflects an effect of aberration of patterns of memory cells through the fine patterns during a calculation of MR (mis-registration).

### CROSS-REFERENCE TO RELATED PATENT APPLICATION

This application claims the benefit of Korean Patent Application No. 10-2007-0027224, filed on Mar. 20, 2007, in the Korean Intellectual Property Office, the disclosure of which is incorporated herein in its entirety by reference.

### FIELD OF THE INVENTION

The present invention relates generally to semiconductor devices, and more particularly, to semiconductor device manufacturing.

### BACKGROUND OF THE INVENTION

A photo lithography process is performed in a process of manufacturing a semiconductor integrated circuit (IC) device to form fine patterns on a semiconductor substrate. The photo lithography process generally includes: coating photoresist (PR) on the semiconductor substrate; baking the semiconductor substrate; matching patterns formed on a mask with patterns formed on a surface of the semiconductor substrate and then exposing the PR through the partial transmission of light; spraying a developer to remove a portion through which light penetrates or does not penetrate during the exposure through a chemical action; and forming patterns on the semiconductor substrate, measuring an alignment state of the patterns, and inspecting for defects.

Here, the process of measuring the alignment state of the patterns on the semiconductor substrate and inspecting the defects is referred to as an overlay process. The overlay process is performed to check whether a lower thin film formed on the semiconductor substrate and an upper thin film formed on the lower thin film are precisely arranged.

Overlay mark patterns are formed on the upper and lower thin films to be used to compare positions of the overlay mark patterns so as to measure the alignment state of the patterns on the semiconductor substrate. Here, Box in Box (BiB) or Frame in Frame (FiF) overlay mark patterns may be used to check the alignment state of two thin films.

However, alignment states of two thin films and three or more thin films may be required to be checked in a semiconductor manufacturing process. In this case, the number of overlay mark patterns required is the same as the number of thin films to be arranged. Also, if a plurality of overlay mark patterns are formed, the plurality of overlay mark patterns occupy a wider space on wafer. Thus, a new design of an overlay mark pattern is required to further effectively use a space.

A current design rule of semiconductor devices is tens of nanometers (nm), while an overlay mark pattern has a size of tens of microns (μm). Thus, a mis-registration (MR) cannot be accurately calculated. In other words, a semiconductor substrate is currently manufactured using a fine process of 90 nm or less. In such a fine process, fine patterns of memory cells have asymmetrical critical dimensions (CDs) or CD shifts due to aberrations of an illumination system. However, since a BiB or FiF overlay mark is manufactured to a very large size of between 20 μm and 30 μm, when the MIR is calculated, the BiB or FiF overlay don't reflect the effect by such aberrations.

The fine patterns of the memory cells are affected by a subsequent process such as etching or chemical mechanical polishing (CMP). Thus, an additional MR, i.e., a wafer induced shift (WIS) occurs. The WIS occurs due to overreaction or underreaction of an overlay mark during the subsequent process such as etching or OMP. Also, in a serious case, the overlay mark is damaged. The damage to the overlay mark may make a measurement value obtained during an arrangement inspection unreliable. Thus, process stability is seriously deteriorated.

### SUMMARY OF THE INVENTION

The present invention provides an overlay mark that is capable of effectively utilizing the space of a wafer, that is capable of being used to align three or more layers, that is capable of reflecting an effect of aberration to accurately measure mis-registration (MR), and that is capable of not being affected by a subsequent process. Also provided are semiconductor devices including the overlay mark.

According to an aspect of the present invention, there is provided an overlay mark of a semiconductor device including: at least one reference marks formed in rectangular shapes comprising sides in which fine patterns are formed; and comparison marks formed as rectangular shapes which are smaller than the rectangular shapes of the at least one reference marks and formed of fine patterns, wherein the number of comparison marks is equal to the number of reference marks, wherein the at least one reference marks and the comparison marks are formed on different thin films formed on a semiconductor substrate to inspect alignment states of the different thin films, and the overlay mark reflects an effect of aberration on patterns of memory cells through the fine patterns during a calculation of MR (mis-registration).

In some embodiments, the fine patterns of the at least one reference mark and the comparison marks may be dots or stripe shape patterns. Sizes of the fine patterns may be adjusted according to conditions of an illumination system. Sizes of the fine patterns may be equal or similar to feature sizes of patterns formed on the different thin films of the semiconductor device.

In some embodiments, four (4) reference marks and four (4) comparison marks are utilized. A first reference mark of the four reference marks and a first comparison mark corresponding to the first reference mark may be disposed on a first quadrant, a second reference mark and a second comparison mark corresponding to the second reference mark may be disposed on a second quadrant, a third reference mark and a third comparison mark corresponding to the third reference mark may be disposed on a third quadrant, and a fourth reference mark and a fourth comparison mark corresponding to the fourth reference mark may be disposed on a fourth quadrant. In some embodiments, the fine patterns are in stripe shapes in a first direction in the first reference and comparison marks, the fine patterns are in dot shapes in the second reference and comparison marks, the fine patterns are formed in stripe shapes in a second direction in the fourth reference and comparison marks, the fine patterns are formed in stripe shapes in the second direction in two facing sides of the third reference mark, the fine patterns are formed in stripe shapes in the first direction in the other two sides of the third reference mark, and the fine patterns are formed in stripe shapes in the second or first direction in the third comparison mark.

In some embodiments, the fine patterns may not be formed at corner portions of the third reference mark or may protrude from corner portions of the third reference mark. The four reference marks and the four comparison marks may be disposed on the four quadrants so that their positions are changed on the four quadrants to improve uniqueness among a plurality of overlay marks so as to improve utilization of a space on a wafer.

In the present invention, the overlay mark can inspect alignment states of two or five thin films using the four reference marks and the four comparison marks. If alignment states of two thin films are inspected, the four reference marks may be formed in a first thin film formed on the semiconductor substrate and the four comparison marks may be formed in a second thin film formed on the first thin film, wherein the four comparison marks are positioned inside corresponding ones of the four reference marks.

In some embodiments, different weights may be applied to the four reference marks and the four comparison marks to improve inspection of alignment states of the thin films.

If alignment states of five thin films are inspected, the first reference mark may be formed in a first thin film formed on the semiconductor substrate, the first comparison mark and the second reference mark may be formed in a second thin film formed on the first thin film, wherein the first comparison mark is positioned inside the first reference mark, the second comparison mark and the third reference mark are formed in a third thin film formed on the second thin film, wherein the second comparison mark is positioned inside the second reference mark, the third comparison mark and the fourth reference mark are formed in a fourth thin film formed on the third thin film, wherein the third comparison mark is positioned inside the third reference mark, and the fourth comparison mark is formed in a fifth thin film formed on the fourth thin film, so as to inspect alignment states of five thin films.

The four reference marks and the four comparison marks may be formed in square shapes so that the overlay mark has a square shape, a length of each side of each of the four reference marks may be 14 μm or less, a width of each side of each of the four reference marks may be 2 μm or less, a length of each side of each of the four comparison marks may be 6 μm or less, separation distances between adjacent ones of the four reference marks may be 2 μm or less, and each side of the overlay mark having the square shape may be 30 μm or less.

According to another aspect of the present invention, there is provided an overlay mark of a semiconductor device including: a mark frame having a rectangular shape, including four rectangular spaces formed in a first thin film formed on a semiconductor substrate and including sides in which fine patterns are formed; and four comparison marks formed in or over the first thin film, positioned in the mark frame, formed of fine patterns, and having rectangular shapes, wherein the four comparison marks are formed in different thin films formed on the semiconductor substrate so as to be used to inspect alignment states of the different thin films, the overlay mark reflects an effect of aberration on patterns of memory cell through the fine patterns during a calculation of MR, and the overlay reflects an effect of aberration on patterns of memory cells is reflected by the overlay mark during a calculation of MR, and the overlay mark is durable to semiconductor manufacturing processes.

In some embodiments, the mark frame and a first comparison mark of the four comparison marks may be formed in a first thin film formed on the semiconductor substrate, a second comparison mark may be formed in a second thin film formed on the first thin film, a third comparison mark may be formed in a third thin film formed on the second thin film, and a fourth comparison mark may be formed in a fourth thin film formed on the third thin film, so as to be used to inspect alignment states of the mark frame and the first through fourth thin films.

According to another aspect of the present invention, there is provided a semiconductor device including: a substrate; a plurality of thin films formed on the substrate; and the overlay mark formed in the plurality of thin films to inspect alignment states of the plurality of thin films.

In some embodiments, a first reference mark of the four reference marks and a first comparison mark corresponding to the first reference mark may be disposed on a first quadrant, a second reference mark and a second comparison mark corresponding to the second reference mark may be disposed on a second quadrant, a third reference mark and a third comparison mark corresponding to the third reference mark may bedisposed on a third quadrant, and a fourth reference mark and a fourth comparison mark corresponding to the fourth reference mark may be disposed on a fourth quadrant. In some embodiments, the fine patterns are in stripe shapes in a first direction in the first reference and comparison marks, the fine patterns are in dot shapes in the second reference and comparison marks, the fine patterns are formed in stripe shapes in a second direction in the fourth reference and comparison marks, the fine patterns are formed in stripe shapes in the second direction in two facing sides of the third reference mark, the fine patterns are formed in stripe shapes in the first direction in the other two sides of the third reference mark, and the fine patterns are formed in stripe shapes in the second or first direction in the third comparison mark.

The semiconductor device can inspect alignment states of two or five thin films at a time using the overlay mark.

An overlay mark according to the present invention can have effective space utilization, align three or more thin films, and form fine patterns having similar sizes to patterns of memory cells so as to reflect an effect of aberration. Also, different weights can be applied to reference marks according to characteristics of the three or more thin films. In addition, an overlay mark including a plurality of reference marks and a plurality of comparison marks can be formed to the same size as an existing overlay mark. Thus, an effective measurement length can be increased and different weights can be applied to the reference marks according to the characteristics of the three or more thin films so as to further accurately calculate MR of a semiconductor device. Furthermore, fine patterns can be formed in the overlay mark to similar sizes to the patterns of memory cells. Thus, the overlay mark can be durable to a subsequent process. As a result, WIS can be prevented from occurring or damage to the overlay mark can be minimized. Therefore, a back-up plan can be made out to cope with an attack against the overlay mark in the subsequent process.

### BRIEF DESCRIPTION OF THE DRAWINGS

The above and other features and advantages of the present invention will become more apparent by describing in detail exemplary embodiments thereof with reference to the attached drawings in which:

FIG. 1A illustrates an overlay mark of a semiconductor device according to an embodiment of the present invention;

FIG. 1B is a magnified view of portion A of FIG. 1A;

FIG. 2 illustrates coordinates for calculating mis-registration (MR) of a semiconductor device;

FIGS. 3A through 3C illustrate dimensions of the overlay mark of FIG. 1A;

FIGS. 4A and 4B are cross-sectional views illustrating the overlay mark of FIG. 1A formed to check alignment states of two thin films formed on a semiconductor substrate, taken along lines I-I and II-II;

FIGS. 5A and 5B are cross-sectional views illustrating the overlay mark of FIG. 1A formed to check alignment states of five thin films formed on the semiconductor substrate, taken along lines I-I and II-II;

FIG. 6 illustrates an overlay mark of a semiconductor device according to another embodiment of the present invention;

FIG. 7 illustrates an overlay mark of a semiconductor device according to another embodiment of the present invention;

FIG. 8 illustrates an overlay mark of a semiconductor device according to another embodiment of the present invention;

FIG. 9A illustrates an overlay mark of a semiconductor device according to another embodiment of the present invention;

FIG. 9B is a magnified view of portion B of FIG. 9A;

FIGS. 10A and 10B are cross-sectional views illustrating the overlay mark of FIG. 9A formed to check alignment states of four thin films formed on a semiconductor substrate, taken along lines III-III and IV-IV; and

FIG. 11 illustrates an overlay mark of a semiconductor device according to another embodiment of the present invention

### DETAILED DESCRIPTION OF THE INVENTION

The present invention is described more fully hereinafter with reference to the accompanying drawings, in which example embodiments of the invention are shown. The present invention may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to,” “coupled to” or “responsive to” another element or layer, it can be directly on, connected, coupled or responsive to the other element or layer or intervening elements or layers may be present. In contrast, when an element is referred to as being “directly on,” “directly connected to,” “directly coupled to” or “directly responsive to” another element or layer, there are no intervening elements or layers present. Like numbers refer to like elements throughout. As used herein, the term “and/or” includes any and all combinations (mixtures) of one or more of the associated listed items and may be abbreviated as “/”.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The structure and/or the device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the present invention are described herein with reference to cross-section illustrations that are schematic illustrations of idealized embodiments (and intermediate structures) of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

It should also be noted that in some alternate implementations, the functionality of a given block may be separated into multiple blocks and/or the functionality of two or more blocks may be at least partially integrated.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and the present application, and will not be interpreted in an idealized or overly formal sense unless expressly so defined herein.

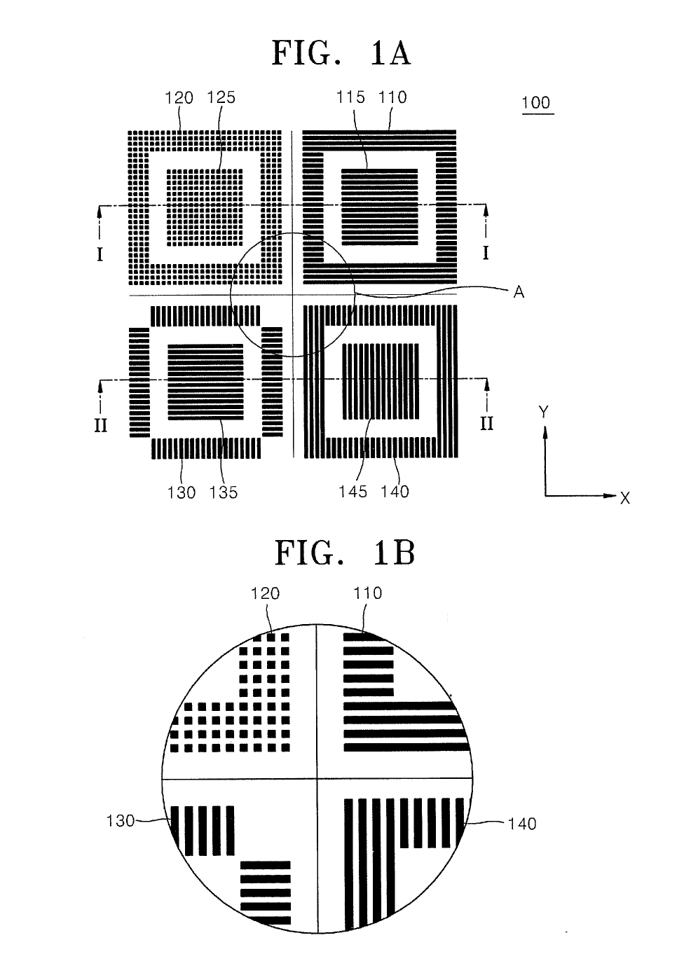

FIG. 1A illustrates an overlay mark of a semiconductor device according to an embodiment of the present invention. Referring to FIG. 1A, an overlay mark 100 of the present embodiment includes first through fourth reference marks 110, 120, 130, and 140 and first through fourth comparison marks 115, 125, 135, and 145. The first through fourth comparison marks 115, 125, 135, and 145 are respectively disposed inside the first through fourth reference marks 110, 120, 130, and 140, as illustrated.

In other words, the first comparison mark 115 is disposed inside the first reference mark 110 disposed on a first quadrant, the second comparison mark 125 is disposed inside the second reference mark 120 disposed on a second quadrant, the third comparison mark 135 is disposed inside the third reference mark disposed on a third quadrant, and the fourth comparison mark 145 is disposed inside the fourth reference mark 140 disposed on a fourth quadrant.

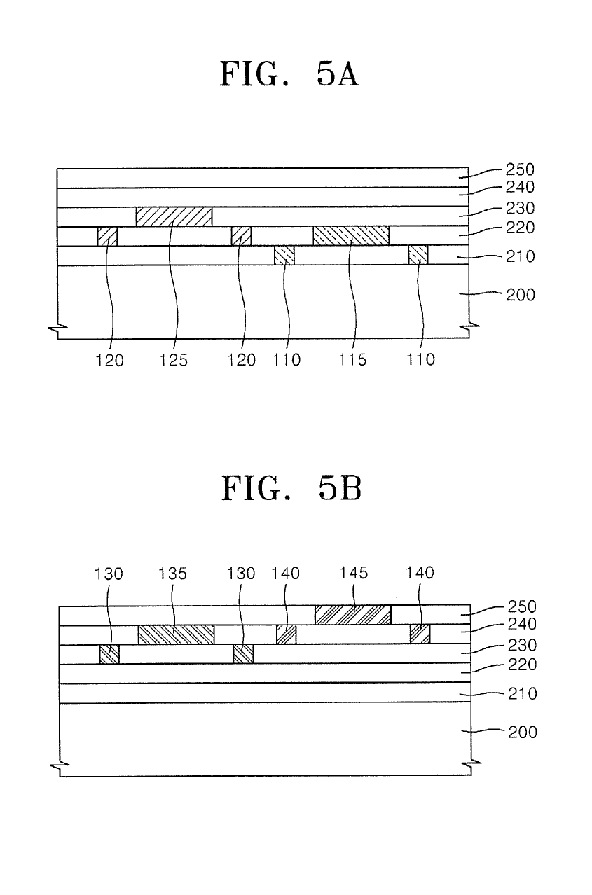

The first through fourth reference marks 110, 120, 130, and 140 are formed on a different thin film from a thin film of a semiconductor substrate on which the first through fourth comparison marks 115, 125, 135, and 145 are formed. Position relationships between the first through fourth reference marks 110, 120, 130, and 140 and the first through fourth comparison marks 115, 125, 135, and 145 are measured through an illumination system to inspect an alignment state between the thin films. The overlay mark 100 of the illustrated embodiment can contribute to inspection of alignment states among a maximum of five thin films through the first through fourth reference marks 110, 120, 130, and 140 and the first through fourth comparison marks 115, 125, 135, and 145. This will be described in more detail later with reference to FIGS. 5A and 5B.

The first through fourth reference marks 110, 120, 130, and 140 are formed in square band shapes, and the first through fourth comparison marks 115, 125, 135, and 145 are formed in square plane shapes which are smaller than those of the first through fourth reference marks 110, 120, 130, and 140 so as to be disposed inside them. Fine patterns are formed on sides of the first through fourth reference marks 110, 120, 130, and 140 having the square frame shapes, and fine patterns are formed on entire surfaces of the first through fourth comparison marks 115, 125, 135, and 145.

Fine patterns of reference and comparison marks, according to embodiments of the present invention may be formed using segments of dot shapes, horizontal line and space shapes, or vertical line and space shapes. For example, stripe shape fine patterns are formed in a Y direction in the first reference comparison marks 110 and 115, dot shape fine patterns are formed in the second reference and comparison marks 120 and 125, and stripe shape fine patterns are formed in an X direction in the fourth reference and comparison marks 140 and 145. Stripe shape fine patterns may be formed in the X direction in two facing sides of the third reference mark 130 and in the Y direction in two other sides, but fine patterns may not be formed at corner portions of the third reference mark 130. Stripe shape fine patterns may be formed in the X direction or the Y direction in the third comparison mark 135.

If reference and comparison marks having various fine patterns are mixed to form a plurality of overlay marks on thin films of a semiconductor substrate, uniqueness of the overlay marks may be improved so that the overlay marks are adjacent to one another. Thus, efficiency of a space on a scribe line of a wafer may be improved.

Also, different weights may be applied to reference and comparison marks according to characteristics of thin films so as to further precisely inspect alignment states in a desired direction during the calculation of MR. For example, if information in the X axis is important, a heavier weight may be applied to vertical line and space shape segments, i.e., the fourth reference and comparison marks 140 and 145 to calculate MR. If information in the Y axis is important, a heavier weight may be applied to horizontal line and space shape segments, i.e., the first reference and comparison marks 110 and 115 to calculate MR. Different weights may be applied as described above to further precisely calculate MR in a desired direction.

The reference and comparison marks may be formed of fine patterns of the same size as or similar size to feature sizes of substantial patterns of memory cells. If fine patterns are formed on an overlay mark to the same sizes or similar size to feature sizes of substantial patterns as described above, the fine patterns may be patterned to have a resolution lower than that of a microscope used in overlay equipment. Thus, although now shown through the microscope, the fine patterns may reflect an effect of aberration. In other words, the overlay mark 100 of the present embodiment can accurately reflect an effect of aberration during the calculation of MR.

In addition, the overlay mark 100 can have fine patterns having the same sizes as or similar sizes as substantial patterns so as to have similar reactivity to the substantial patterns. Thus, wafer induced shift (WIS) can be immediately calculated, and the overlay mark 100 can be prevented from being damaged. If many fine patterns are normally formed, the overlay mark 100 can have a structure robust to etching or chemical mechanical polishing (CMP) through an improvement of an open ratio.

FIG. 1B is a magnified view of portion A of FIG. 1A. Referring to FIG. 1B, the first through fourth reference marks 110, 120, 130, and 140 have fine patterns with different shapes. Sizes of the fine patterns may be determined according to design rules of patterns of memory cells as described above. Thus, the fine patterns may have sizes of tens of nm.

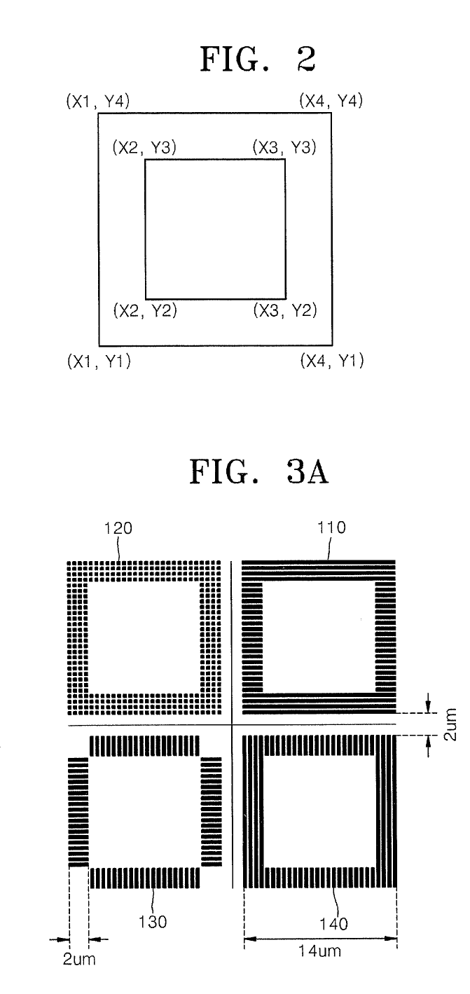

FIG. 2 illustrates coordinates for calculating MR of a semiconductor device. Here, the MR is calculated using a normal method. Also, X1 and X4 denote X coordinates of a reference mark, X2 and X3 denote X coordinates of a comparison mark, Y1 and Y4 denote Y coordinates of the reference mark, and Y2 and Y3 denote Y coordinates of the comparison mark. An X-axis MRₓ value between the reference and comparison marks is calculated as in Equation 1:

MRₓ=0.5×{(X2+X3)−(X1+X4)}. (1)

A Y-axis MR_{y} value between the reference and comparison marks is calculated as in Equation 2:

MR_{y}=0.5×{(Y2+Y3)−(Y1+Y4)}. (2)

If an alignment state between layers is precisely performed, X-axis MRₓ and Y-axis MR_{y} values are zero according to Equations 1 and 2.

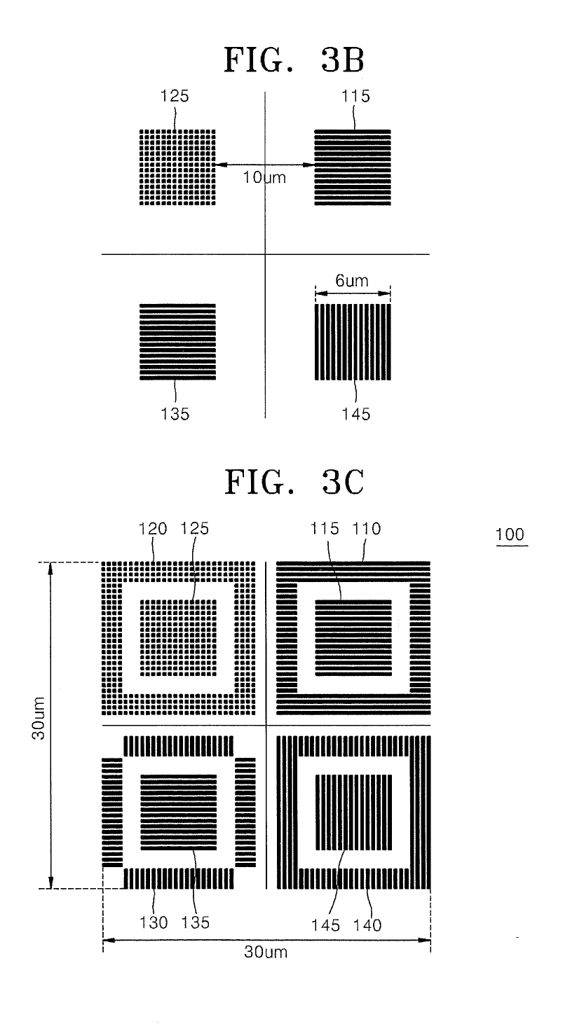

An overlay mark of the present embodiment includes four reference marks and four comparison marks so as to further accurately calculate X-axis MRₓ and Y-axis MR_{y} values. In other words, the overlay mark 100 of the illustrated embodiment has a total size between 25 μm and 35 μm and thus has a similar size to a BiB or FiF overlay mark. Thus, the overlay mark 100 of the illustrated embodiment can calculate MR using a larger amount of position information. A measured length of the overlay mark 100 of the illustrated embodiment can be increased two times that of an existing BiB overlay mark. For example, if the overlay mark 100 of the illustrated embodiment replaces a 30 μm BiB overlay, the measured length of the overlay mark 100 of the illustrated embodiment is increased from 120 μm to about 224 μm. The size of the overlay mark 100 of the illustrated embodiment will be described in more detail later with reference to FIGS. 3A through 3B.

In the overlay mark 100 of the illustrated embodiment, fine patterns are formed on reference marks and comparison marks. Thus, when a position of the overlay mark 100 is measured, the position of the overlay mark 100 can be detected using a larger amount of information. Thus, MR can be accurately calculated.

FIGS. 3A through 3C illustrate the dimensions of the overlay mark 100 of FIG. 1A.

FIG. 3A illustrates the first through fourth reference marks 110, 120, 130, and 140. Referring to FIG. 3A, the first through fourth reference marks 110, 120, 130, and 140 have square band shapes sides of which each have a length of 14 μm and a width of 2 μm. The first through fourth reference marks 110, 120, 130, and 140 are regularly arranged around the origin of the X and Y axes and are separated from each other by distances of 2 μm. Thus, the overlay mark has a square shape. Shapes and sizes of fine patterns formed on the first through fourth reference marks 110, 120, 130, and 140 are as described in FIG. 1A. The first through fourth reference marks 110, 120, 130, and 140 may be formed on the same thin film but may be formed on different layers if alignment states of three or more thin films are to be inspected.

FIG. 3B illustrates the first through fourth comparison marks 115, 125, 135, and 145. Referring to FIG. 3B, the first through fourth comparison marks 115, 125, 135, and 145 have square plane shapes sides of which each have a length of 6 μm. Various types of fine patterns are formed inside the first through fourth comparison marks 115, 125, 135, and 145. If the first through fourth comparison marks 115, 125, 135, and 145 are in correct arrangement positions, the first through fourth comparison marks 115, 125, 135, and 145 are separated by distances of about 10 μm from each other. The first through fourth comparison marks 115, 125, 135, and 145 may be formed on the same thin film but may be formed on different layers if alignment states of three or more thin films are to be inspected.

FIG. 3C illustrates the first through fourth reference mark 110. 120. 130, and 140, and the first through fourth comparison mark 115. 125. 135, and 145 together to show the total size of the overlay.

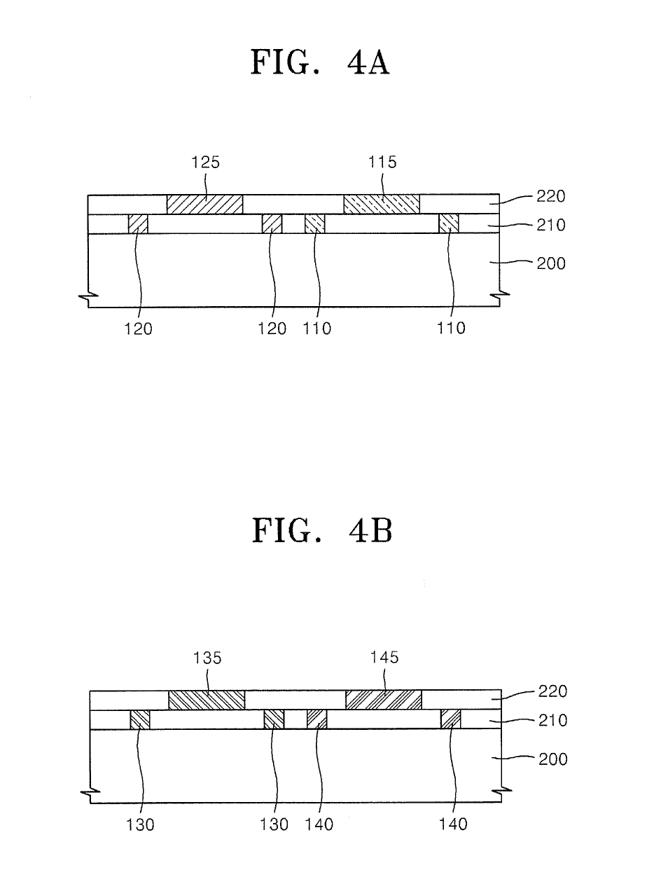

FIGS. 4A and 4B are cross-sectional views illustrating the overlay mark of FIG. 1A formed to inspect an alignment state between two thin films formed on a semiconductor substrate, taken along lines I-I and II-II.

Referring to FIG. 4A, first and second reference marks 110 and 120 are formed in a first thin film 210 formed on a semiconductor substrate 200. First and second comparison marks 115 and 125 are formed in a second thin film 220 formed on the first thin film 210. Alignment states of the first and second thin films 210 and 220 are inspected through position relationships between the first and second reference and comparison marks 110, 120, 115, and 125, i.e., by calculation of MR using Equations 1 and 2 above.

Referring to FIG. 4B, third and fourth reference marks 130 and 140 are formed in the first thin film 210, and third and fourth comparison marks 135 and 145 are formed in the second thin film 220. As described with reference to FIG. 4A, the third and fourth reference and comparison marks are used to calculate MR.

An overlay mark, according to embodiments of the present invention, can use four reference marks and four comparison marks to further accurately calculate MR. As described above, different weights can be applied to the four reference marks and the four comparison marks to further precisely inspect an interlayer alignment state in an important direction depending on characteristics of thin films.

FIGS. 5A and 5B are cross-sectional views illustrating the overlay mark 100 of FIG. 1A formed to inspect alignment states among five thin films formed on a semiconductor substrate, taken along lines I-I and II-II.

Referring to FIG. 5A, first reference marks 110 are formed in a first thin film 210 formed on a semiconductor substrate 200, a first comparison mark 115 and second reference marks 120 are formed in a second thin film 220 formed on the first thin film 210. Also, a second comparison mark 125 is formed in a third thin film 230 formed on the second thin film 220. As described above, the first and second reference marks 110 and 120 and the first and second comparison marks 115 and 125 can be formed to inspect alignment states of the first, second, and third thin films 210, 220, and 230 simultaneously.

Referring to FIG. 5B, third reference marks 130 are formed in the third thin film 230, a third comparison mark 135 and fourth reference marks 140 are formed in a fourth thin film 240, and a fourth comparison mark 145 is formed in a fifth thin film 250. Thus, alignment states of the third, fourth, and fifth thin films 230, 240, and 250 can be inspected simultaneously.

Accordingly, the overlay mark 100 of the illustrated embodiment can inspect alignment states between five thin films simultaneously. In other words, in a case of an existing BiB or FiF overlay, a number of overlay marks equal to a number of thin films are required to align three or more thin films, and the existing BiB or FiF overlay is disadvantageous in terms of utilization of space on wafer. However, in the case of the overlay mark 100 of the illustrated embodiment, alignment states of three or more thin films can be inspected using one overlay mark. Thus, the utilization of space on a wafer can be considerably improved. Also, since alignment states of a plurality of thin films can be inspected simultaneously, the time required for calculating MR for checking alignment states can be reduced.

The improvement of the utilization of wafer space can result in the improvement of integration of a semiconductor device, and the reduction of the time required for calculating the MR can result in improvement of productivity of a semiconductor manufacturing process.

Structures of overlay marks formed for inspecting alignment states of two thin films and five thin films have been exemplarily described with reference to FIGS. 5A and 5B. However, reference and comparison marks of the overlay mark 100 of the illustrated embodiment can be appropriately disposed to inspect alignment states between three thin films and four thin films.

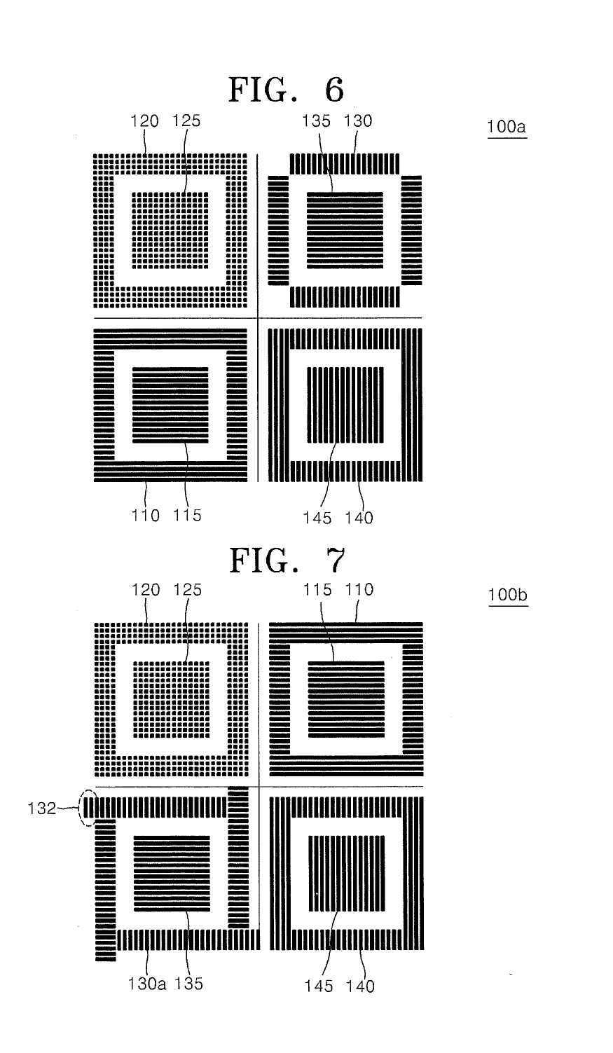

FIG. 6 illustrates an overlay mark of a semiconductor device according to another embodiment of the present invention. Referring to FIG. 6, an overlay mark 100a of the illustrated embodiment is similar to the overlay mark 100 of FIG. 1A but has differences from the overlay mark 100 in terms of position relationships between reference and comparison marks. In other words, in the overlay mark 100a of the illustrated embodiment, third reference and comparison marks 130 and 135 are disposed on a first quadrant, and first reference and comparison marks 110 and 115 are disposed on a third quadrant. Shapes and sizes of fine patterns of the overlay mark 100a, an entire size of the overlay mark 100a, etc. are as described with reference to FIGS. 1A and 3.

Positions of the third reference and comparison marks 130 and 135 are unique compared to reference and comparison marks disposed on different quadrants and can be changed to distinguish the overlay mark 100a from another overlay mark, e.g., the overlay mark 100 of FIG. 1A.

In other words, uniqueness of each overlay mark can be improved. Therefore, a plurality of overlay marks on a semiconductor substrate are formed to be adjacent to one another. Thus, the utilization of a space on a scribe line of a wafer can be further improved.

FIG. 7 illustrates an overlay mark of a semiconductor device according to another embodiment of the present invention. Referring to FIG. 7, an overlay mark 100b of the illustrated embodiment is similar to the overlay mark 100 of FIG. 1A but has differences from the overlay mark 100 in terms of shapes of fine patterns of a third reference mark 130a. In other words, fine patterns are not formed at corner portions of the third reference mark of FIG. 1A, but fine patterns 132 are formed to protrude from four corner portions of the third reference mark 130a, as illustrated.

In the overlay mark 100b of the present embodiment, the corner fine patterns 132 can be formed to improve uniqueness from other overlay marks so as to improve the utilization of a space on a wafer as described with reference to FIG. 6.

It has been described in the present embodiment and FIGS. 1A and 6 that a third reference mark is formed differently from other reference marks to improve uniqueness of an overlay mark. However, other reference marks may be formed in a unique shape to improve uniqueness of the overlay mark. Also, the unique shape is not limited to a protruding shape or gaps.

FIG. 8 illustrates an overlay mark of a semiconductor device according to another embodiment of the present invention. Referring to FIG. 8, an overlay mark 100c of the illustrated embodiment is similar to the overlay mark 100 of FIG. 1A but has differences from the overlay mark 100 in terms of shapes of fine patterns of comparison marks. In other words, each of first through fourth comparison marks 115a, 125a, 135a, and 145a includes four square portions. For example, two square portions disposed in one diagonal direction have stripe shape fine patterns disposed in the X direction, and two portions disposed in an other diagonal direction have stripe shape fine patterns disposed in the Y direction.

Such fine patterns can be formed in the first through fourth comparison marks 115a, 125a, 135a, and 145a to increase an open ratio of the fine patterns so as to form an overlay mark more robust to changes of processes. The sizes or shapes of the fine patterns, the entire size of an overlay mark, etc., described above with reference to FIGS. 3A-3C can be applied in the illustrated embodiment. However, the illustrated invention is not limited to the sizes described above and can be modified as required.

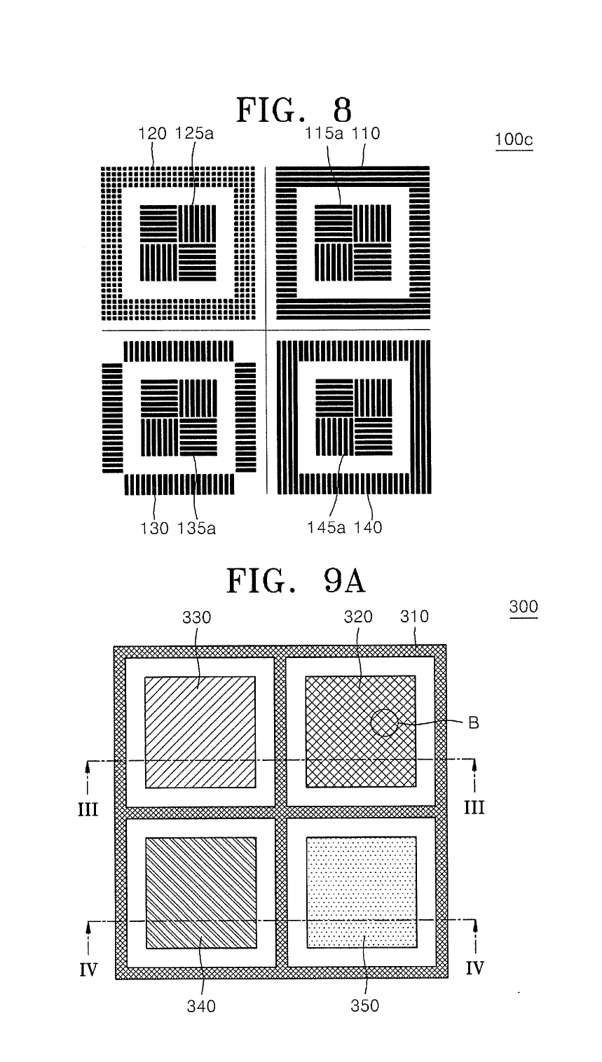

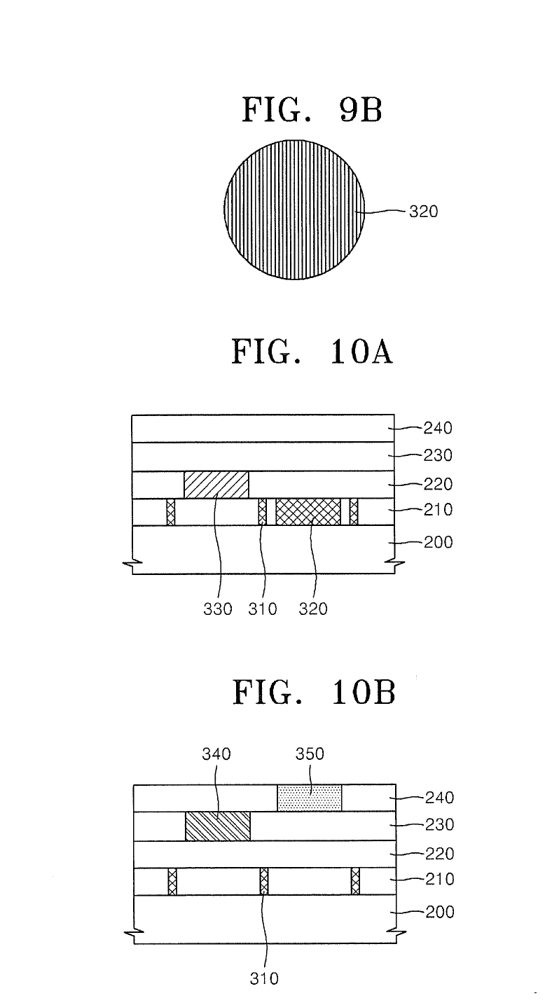

FIG. 9A illustrates an overlay mark of a semiconductor device according to another embodiment of the present invention. Referring to FIG. 9A, an overlay mark 300 of the present embodiment includes a mark frame 310 and first through fourth comparison marks 320, 330, 340, and 350. The mark frame 310 includes four squares, and the first through fourth comparison marks 320, 330, 340, and 350 are respectively disposed in the four squares, as illustrated.

Fine patterns are formed in side portions of the mark frame 310, and fine patterns are formed in entire surfaces of the first through fourth comparison marks 320, 330, 340, and 350. The fine patterns may be formed in dot or stripe shapes as described with reference to FIG. 1A to have similar sizes to those of fine patterns of memory cells so as to prevent an effect of aberration, WIS and damages to an overlay mark, etc.

FIG. 9B is a magnified view illustrating portion B of FIG. 9A. Referring to FIG. 9B, the first comparison mark 320 disposed on a first quadrant has stripe shaped fine patterns disposed in the X direction. The mark frame 310 and the second through fourth comparison marks 330, 340, and 350 may have the same fine patterns as the first comparison mark 320 but may have different shapes from the first comparison mark 320 to improve uniqueness of an overlay mark.

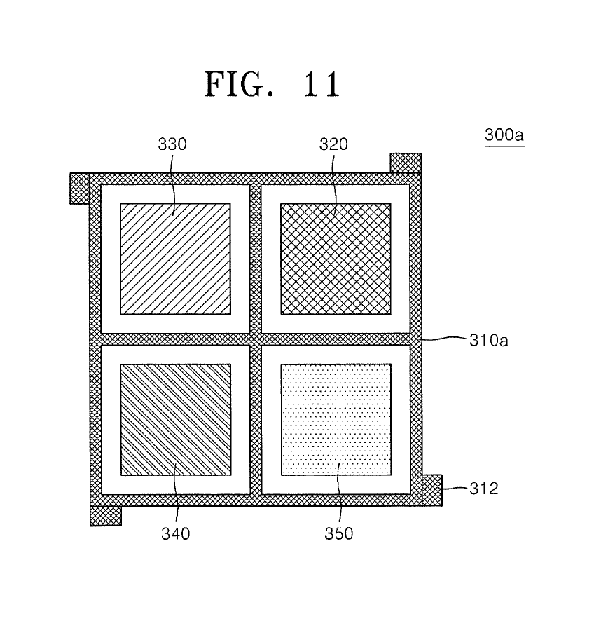

FIGS. 10A and 10B are cross-sectional views illustrating the overlay mark 300 of FIG. 9a formed to inspect alignment states among four thin films formed on a semiconductor substrate, taken along lines III-III and IV-IV.

Referring to FIG. 10A, the mark frame 310 and the first comparison mark 320 are formed in a first thin film 210 formed on a semiconductor substrate 200, and the second comparison mark 330 is formed in a second thin film 220. Here, the mark frame 310 is formed to quantitate misalignment caused by changes of processes, i.e., MR. The frame mark 310 is normally formed in the first thin film 210 which is slightly changed during processes.

A length of a side of the mark frame 310 may be similar to a length of a side of a BiB or FiF overlay mark, i.e., may be within a range between 20 μm and 40 μm. The first and second comparison marks 320 and 330 are positioned inside lattices of the mark frame 310 disposed on first and second quadrants. Thus, alignment states of the first and second thin films 210 and 220 can be inspected. An MR value in the present embodiment can be calculated using Equations 1 and 2, described above.

Referring to FIG. 10B, the mark frame 310 is formed in the first thin film 210, the third comparison mark 340 is formed in a third thin film 230, and the fourth comparison mark 350 is formed in a fourth thin film 240. Alignment states of the third and fourth thin films 230 and 240 can be inspected.

The overlay mark 300 of the illustrated embodiment can be used to inspect alignment states of four thin films simultaneously. Thus, as in the embodiment described with reference to FIG. 1A, the utilization of a space on a wafer can be considerably improved, and the time required for calculating MR for checking alignments can be reduced.

FIG. 11 illustrates an overlay mark of a semiconductor device according to another embodiment of the present invention. Referring to FIG. 11, an overlay mark 300a of the illustrated embodiment is similar to the overlay mark 300 of FIG. 9A but has differences from the overlay mark 300 in terms of the mark frame. In other words, corner fine patterns 312 are formed to protrude from corner portions of a mark frame 310a of the illustrated embodiment. A unique shape can be added to the mark frame 310a to improve uniqueness of the overlay mark 300a as described with reference to FIG. 6. Thus, the utilization of space on a wafer can be improved. The corner fine patterns 312 are not limited to shapes of the illustrated embodiment but may have any shapes that can be used to improve uniqueness of an overlay mark.

As described above, in an overlay mark of a semiconductor device and a semiconductor device including the overlay mark according to some embodiments of the present invention, alignment states of a plurality of thin films can be inspected simultaneously. Thus, the time required for checking alignments of the plurality of thin films can be reduced.

Also, the alignment states of the plurality of thin films can be inspected using one overlay mark. Thus, the utilization of a space on a wafer can be improved. As a result, integration of a semiconductor integrated circuit (IC) can be improved.

In addition, an overlay mark, according to embodiments of the present invention, can include various fine patterns adopting the same design rules as fine patterns of memory cells so as to reflect an effect of aberration during a calculation of MR. Thus, the alignment states of the plurality of thin films can be further precisely inspected.

Moreover, fine patterns can be formed in the overlay mark to be affected by the same effects as the patterns of the memory cells in a subsequent process. Also, marks having robust structures can be formed due to an increase of an open ratio. Thus, additional marks are not required to calculate WIS, and damage to the overlay mark can be prevented. As a result, productivity of semiconductor devices can be considerably improved.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. An overlay mark of a semiconductor device comprising:
at least one reference mark formed in a rectangular shape and comprising sides in which fine patterns are formed; and
at least one comparison mark formed in a rectangular shape smaller than the rectangular shape of the at least one reference mark and formed of fine patterns, wherein the number of comparison marks is equal to the number of reference marks,
wherein the at least one reference mark and comparison mark are formed on different thin films formed on a semiconductor substrate to facilitate inspection of alignment states of the thin films, and wherein the overlay mark reflects an effect of aberration on patterns of memory cells through the fine patterns during a calculation of MR (mis-registration).

2. The overlay mark of claim 1, wherein the fine patterns of the at least one reference mark and the comparison mark comprise dots or stripe shape patterns.

3. The overlay mark of claim 2, wherein at least one reference mark comprises four (4) reference marks and wherein at least one comparison mark comprises four (4) comparison marks, one of the at least one reference marks and one of the comparison marks are disposed on each of four quadrants of the overlay mark, wherein the overlay mark has a rectangular shape, and wherein each comparison mark is disposed inside a respective reference mark.

4. The overlay mark of claim 3, wherein a first reference mark of the four reference marks and a first comparison mark corresponding to the first reference mark are disposed on a first quadrant, a second reference mark and a second comparison mark corresponding to the second reference mark are disposed on a second quadrant, a third reference mark and a third comparison mark corresponding to the third reference mark are disposed on a third quadrant, and a fourth reference mark and a fourth comparison mark corresponding to the fourth reference mark are disposed on a fourth quadrant, wherein the fine patterns comprise stripe shapes in a first direction in the first reference and comparison marks, wherein the fine patterns comprise dot shapes in the second reference and comparison marks, wherein the fine patterns comprise stripe shapes in a second direction in the fourth reference and comparison marks, wherein the fine patterns comprise stripe shapes in the second direction in two facing sides of the third reference mark, wherein the fine patterns comprise stripe shapes in the first direction in the other two sides of the third reference mark, and wherein the fine patterns comprise stripe shapes in the second or first direction in the third comparison mark.

5. The overlay mark of claim 4, wherein corner portions of the third reference mark are devoid of the fine patterns.

6. The overlay mark of claim 4, wherein fine patterns protrude from corner portions of the third reference mark.

7. The overlay mark of claim 4, wherein the four reference marks and the four comparison marks are configured to facilitate inspection of alignment states of at least two thin films.

8. The overlay mark of claim 7, wherein the four reference marks are formed in a first thin film formed on the semiconductor substrate and the four comparison marks are formed in a second thin film formed on the first thin film so as to facilitate inspection of the alignment states of the at least two thin films, wherein the four comparison marks are positioned inside corresponding ones of the four reference marks.

9. The overlay mark of claim 8, wherein different weights are applied to the four reference marks and the four comparison marks to improve inspection of alignment states of the thin films.

10. The overlay mark of claim 7, wherein the four reference marks and the four comparison marks are disposed in thin films formed on the semiconductor substrate so as to facilitate inspection of alignment states of three or five thin films.

11. The overlay mark of claim 10, wherein
the first reference mark is formed in a first thin film formed on the semiconductor substrate, the first comparison mark and the second reference mark are formed in a second thin film formed on the first thin film, wherein the first comparison mark is positioned inside the first reference mark, the second comparison mark and the third reference mark are formed in a third thin film formed on the second thin film, wherein the second comparison mark is positioned inside the second reference mark, the third comparison mark and the fourth reference mark are formed in a fourth thin film formed on the third thin film, wherein the third comparison mark is positioned inside the third reference mark, and the fourth comparison mark is formed in a fifth thin film formed on the fourth thin film, wherein the fourth comparison mark is positioned inside the fourth reference mark so as to facilitate inspection of alignment states of five thin films.

12. The overlay mark of claim 3, wherein each of the four comparison marks is divided into four rectangular portions, wherein stripe shaped fine patterns are formed in the second direction in two of the four rectangular portions formed along one diagonal direction and in the first direction in the other two of the four rectangular portions formed along another diagonal direction.

13. An overlay mark of a semiconductor device comprising:
a mark frame having a rectangular shape, comprising four rectangular spaces formed in a first thin film formed on a semiconductor substrate and comprising sides in which fine patterns are formed; and
four comparison marks formed in or over the first thin film, positioned in the mark frame, formed of fine patterns, and having rectangular shapes,
wherein the four comparison marks are formed in different thin films formed on the semiconductor substrate so as to be used to inspect alignment states of the different thin films, and wherein the overlay mark reflects an effect of aberration on patterns of memory cells through the fine patterns during a calculation of MR (mis-registration).

14. The overlay mark of claim 13, wherein protrusions are formed at corner portions of the mark frame.

15. The overlay mark of claim 13, wherein
the mark frame and a first comparison mark of the four comparison marks are formed in a first thin film formed on the semiconductor substrate, a second comparison mark is formed in a second thin film that is formed on the first thin film, a third comparison mark is formed in a third thin film that is formed on the second thin film, and a fourth comparison mark is formed in a fourth thin film that is formed on the third thin film, so as to be used to inspect alignment states of the mark frame and the first through fourth thin films.

16. A semiconductor device comprising:
a substrate;
a plurality of thin films formed on the substrate; and
the overlay mark of claim 1 formed in the plurality of thin films to facilitate inspection of alignment states of the plurality of thin films.

17. The semiconductor device of claim 16, wherein the reference and comparison marks comprise dots or striped shaped fine patterns.

18. The semiconductor device of claim 17, wherein:
the at least one reference mark comprises four (4) reference marks and the at least one comparison mark comprises four (4) comparison marks; and
one of the reference marks is disposed on each of four quadrants of the overlay mark, and a corresponding comparison mark is disposed inside the reference mark,
wherein the overlay mark has a rectangular shape.

19. The semiconductor device of claim 18, wherein a first reference mark of the four reference marks and a first comparison mark corresponding to the first reference mark are disposed on a first quadrant, a second reference mark and a second comparison mark corresponding to the second reference mark are disposed on a second quadrant, a third reference mark and a third comparison mark corresponding to the third reference mark are disposed on a third quadrant, and a fourth reference mark and a fourth comparison mark corresponding to the fourth reference mark are disposed on a fourth quadrant, wherein the fine patterns comprise stripe shapes in a first direction in the first reference and comparison marks, the fine patterns comprise dot shapes in the second reference and comparison marks, the fine patterns comprise stripe shapes in a second direction in the fourth reference and comparison marks, the fine patterns comprise stripe shapes in the second direction in two facing sides of the third reference mark, the fine patterns comprise stripe shapes in the first direction in the other two sides of the third reference mark, and the fine patterns comprise stripe shapes in the second or first direction in the third comparison mark.

20. The semiconductor device of claim 19, wherein the four reference marks and the four comparison marks are configured to facilitate inspection of alignment states of at least two thin films.
